(19) United States
(12) Patent Application Publication
(10) Pub. No.: US 2009/0321934 A1
(43) Pub. Date: Dec. 31, 2009

(54) SELF-ALIGNED CAP AND BARRIER

(76) Inventors: Adrien R. Lavoie, Beaverton, OR (US); Florian Gstrein, Portland, OR (US)

Correspondence Address: CENTURY IP GROUP, INC. [Intel], C/O CPA GLOBAL, P.O BOX 52050, MINNEAPOLIS, MN, 55402, US

(21) Appl. No.: 12/165,016

(22) Filed: Jun. 30, 2008

(51) Int. Cl. H01L 23/52; H01L 21/4763

(52) U.S. Cl. 257/751; 438/637; 257/E23.141; 257/E21.495

(57) ABSTRACT

A semiconductor device comprising an insulator layer formed on a substrate; a via formed by etching into the insulator layer to a first depth; a first metal layer formed over the insulator layer; a second metal layer deposited on the first metal layer to substantially fill the via; a metal-dopant alloy layer deposited over the second metal, wherein the dopant is diffused by annealing through the second metal layer and the first metal layer deposited in the via, such that the dopant migrates to a boundary between the first metal layer and the insulator to form a barrier; and an etch stop layer deposited over the via after planarization of the via and the insulator layer to form a barrier cap.

### BACKGROUND

Electromigration (EM) is the transport of material caused by the gradual movement of the ions in a conductor due to the momentum transfer between conducting electrons and diffusing metal atoms. Atomic migration under an electronic migration may lead to the formation of grain boundaries in the conductor with impurities accumulating and resulting in added resistance and overheating. This result accelerates impurity migration to the grain boundaries, eventually causing performance degradation and failure. Such effect is important in applications where high direct current densities are used, such as in microelectronics and related structures.

As the size of electronic integrated circuits (ICs) decreases (e.g., going from very large-scale IC (VLSI) to ultra-large-scale IC (ULSI)), the practical significance of the noted EM effect increases. Since EM is a function of decreased interconnect dimensions, it can seriously limit performance and reliability. EM in the worst case, leads to the eventual loss of one or more connections and intermittent failure of the entire circuit.

A reduction of the structure dimension in a circuit by a factor k increases the power density proportional to k and the current density by k2 whereby EM effects become predominant. As such, with increasing miniaturization, the probability of failure due to EM increases in VLSI and ULSI circuits due to an increase in power and current density. Systems and methods are needed to overcome the above-mentioned problems.

### BRIEF DESCRIPTION OF THE DRAWINGS

Embodiments of the present invention are understood by referring to the figures in the attached drawings, as provided below.

FIG. 1 illustrates a method for fabricating a self-forming electromigration barrier between a metal layer (e.g., Cu) and an insulator, in accordance with one embodiment.

FIG. 2 illustrates a method for fabricating a self-aligned interconnect cap, in accordance with one embodiment.

FIG. 3A provides secondary ion mass spectroscopy (SIMS) data for CuMn+Cu directly on ILD showing pre-anneal distribution of Cu adjacent to the ILD wall, in accordance with one embodiment.

FIG. 3B provides secondary ion mass spectroscopy (SIMS) data for CuMn+Cu directly on ILD showing post-anneal distribution of Cu adjacent to the ILD wall, in accordance with one embodiment.

Features, elements, and aspects of the invention that are referenced by the same numerals in different figures represent the same, equivalent, or similar features, elements, or aspects, in accordance with one or more embodiments.

### DETAILED DESCRIPTION OF EXEMPLARY EMBODIMENTS

A method for fabricating a self-forming barrier to electromigration, with direct metal adhesion to an insulator is provided. In accordance with one embodiment, a method for fabricating a self-forming electromigration barrier comprises depositing a selected metal (e.g., Cu) seed layer on a layer of insulator disposed on a substrate, wherein the insulator includes at least a via; electroless plating the metal onto the deposited metal layer, such that the via is substantially filled; depositing, by plasma vapor deposition, a selected dopant alloy of said metal (e.g., Cu+dopant); annealing the substrate to diffuse the dopant through the metal toward an interface between the metal and the insulator to form a barrier layer at the wall of the via; removing the metal layer by chemical-mechanical planarization (CMP) to expose the insulator; and forming an etch-stop layer over the substrate to cap the metal-filled via.

In the following, one or more embodiments are disclosed by way of example as applicable to a Cu seed layer selected as the metal layer deposited on the substrate. It is noteworthy, however, that in other implementations any other suitable metal may be utilized instead of Cu. As such, the scope of the claims and this disclosure shall not be construed as limited to Cu as disclosed in the exemplary embodiments herein.

In accordance with one embodiment, a method of fabricating a self-aligned interconnect cap comprises depositing a Cu seed layer on a layer of insulator having one or more vias, wherein the insulator is disposed on a substrate; depositing a selected dopant alloy of Cu on the insulator; electroless plating the Cu onto the deposited Cu-dopant alloy, such that the vias are substantially filled; removing a top surface layer of Cu by chemical-mechanical planarization (CMP) to expose the insulator; and annealing the Cu-dopant alloy layer in an oxidizing atmosphere to diffuse the dopant through the Cu toward an interface between the Cu and the insulator to form a barrier layer and a self-aligned oxidized layer of the dopant as a cap on the upper surface of the Cu.

In accordance with one embodiment, a Cu interconnect with a self-forming electromigration barrier comprises a first insulator formed on a substrate, wherein one or more vias and/or wells are formed by etching into the insulator to a selected depth. A conformal Cu seed layer may be formed on the insulator. Electroless plating may be utilized to deposit Cu over the seed layer to substantially fill the one or more vias and/or wells. A selected dopant alloy of Cu may be deposited over the electroless plated Cu. The dopant may be diffused by annealing through the Cu layers to migrate to the boundary between the Cu and the insulator. Certain layers of Cu may be deposited with an over-burden on the top surface of the insulator, and then removed by CMP planarization. An etch stop layer may be deposited over the Cu-filled vias and/or wells to form a barrier cap.

A self-aligned cap formed on an interconnect well or via, according to one embodiment, includes an insulator; one or more vias and/or wells formed by etching into the insulator layer to a selected depth; a conformal Cu seed layer deposited on the insulator; a layer of dopant alloy of Cu formed over the seed layer, wherein the dopant comprises one or more of Mn, Sn, Mg, B, Ti and Al or a combination thereof. In one embodiment, Cu may be formed by electroless plating in the vias and/or wells to substantially fill the vias and/or wells to the surface of the insulator formed on the substrate. Any overburden deposit of seed Cu, dopant alloy of Cu and electroless-deposited Cu may be removed by CMP to expose the insulator; and a cap may be formed over the top of the remaining electroless plated Cu and seed layer Cu by an annealing diffusion of the dopant to the top surface of the Cu and in an oxidizing atmosphere to form an oxide of the dopant.

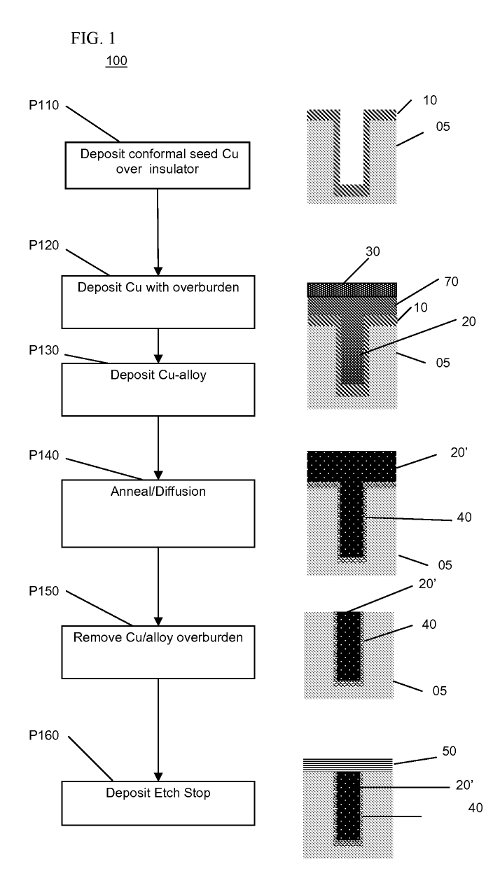

FIG. 1 illustrates a method 100 for fabricating a self-forming barrier with direct Cu adhesion to one or more surfaces of an insulator 05 formed on a substrate, in accordance with one embodiment. The substrate may be a semiconductor. Method 100 comprises depositing a conformal Cu seed layer 10 over insulator 05 (P110). The insulator 05 may comprise an oxide, such as SiO₂, a nitride, such as Si₃N₄. Alternatively, insulator 05 may comprise an interlayer dielectric which may have a low dielectric constant (low-k ILD). Other insulator materials may also be used, depending on implementation.

In one embodiment, insulator 05 may have a plurality of vias, holes, wells or trenches formed therein. The conformal Cu seed layer 10 may be formed by depositing Cu on the inner walls and bottom of the vias, wells and/or trenches, as well as the top surface of the substrate, to provide seeding for further growth of Cu, as provided in further detail below. Cu seed layer 10 may be deposited using various methods, including vacuum evaporation, plasma sputter deposition, chemical vapor deposition, atomic layer deposition, or a metal immobilization process to activate a surface for electrochemical deposition, such as electroless plating (P110).

Referring back to FIG. 1, a second Cu layer 20 may be deposited over the Cu seed layer 10 (P120). The second Cu layer 20 may be deposited by way of electroless (EL) deposition, wherein the Cu fills the vias, wells, and/or trenches. In some embodiments, Cu seed layer 10 and second Cu layer 20 may overfill the vias to the extent that a Cu over-burden 70 may be formed. That is, an excess amount of Cu may substantially cover the top surface of the insulator 05. A Cu-dopant alloy 30 may be deposited over the second Cu layer 20 and Cu overburden 70 (P130). Cu-dopant alloy 30 may be deposited by way of plasma vapor deposition (PVD) over the second Cu layer 20, or any other suitable scheme. The Cu-dopant alloy 30 may comprise one or more of Mn, Mg, B, Sn, Ti, and Al, or a combination thereof.

The substrate and materials deposited over the substrate, as noted above, may be subjected to a diffusion annealing (P140), such that the Cu-dopant alloy 30 diffuses through the second Cu layer 20 and the Cu overburden 70 to the extent that a large portion of Cu-dopant alloy 30 accumulates at the interface of the deposited Cu seed layer 20 and the oxide or dielectric surface of insulator 05, leaving Cu seed layer 20 as a post anneal/post diffusion Cu 20′. The Cu-dopant alloy 30 may form a barrier 40 of metal oxide at the interface with the insulator 05 where the insulator 05 comprises SiO₂, for example. Alternatively, barrier 40 comprising a metal nitride may be formed, where the insulator 05 comprises a nitride, for example.

Barrier 40 may have the property to prevent electromigration of atoms between the second Cu layer 20 and the insulator 05 to maintain the insulating qualities of insulator 05, and the conductive properties of the second Cu layer 20. A chemical-mechanical planarization (CMP) may be performed to remove Cu and Cu-dopant alloy overburdens (P150), desirably exposing insulator 05. Suitable cleaning processes may be applied to clean the resulting exposed surface of insulator 05 and Cu 20′.

An etch stop 50 may be deposited to cover at least the exposed Cu 20′ and barrier 40 (P160). Etch stop 50 may also cover portions of insulator 05 to provide an effective barrier against electromigration between Cu 20′ and insulator 05 and to preserve the conductive quality of the second Cu layer 20. SiCN may be used as a barrier etch stop, in one embodiment. In other embodiments, SiN or SiC may alternatively be used as an electromigration barrier etch stop.

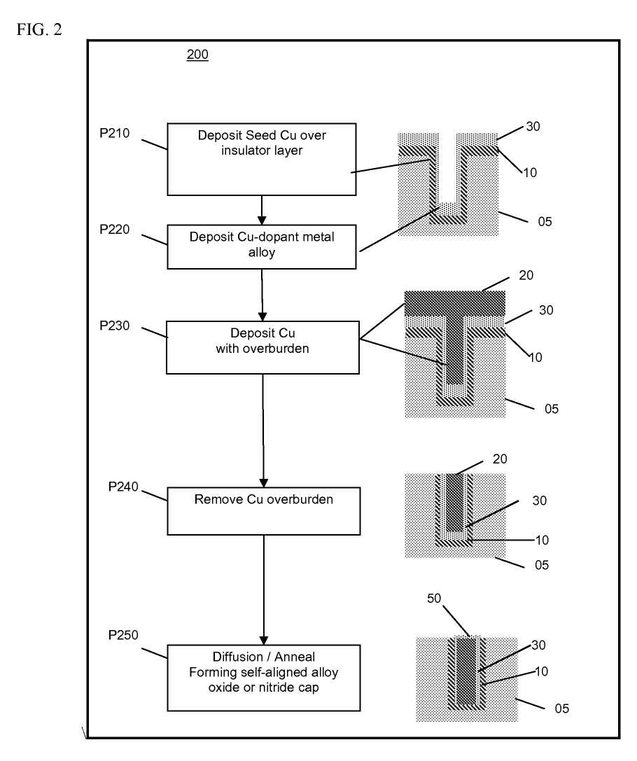

FIG. 2 illustrates a method 200 for fabricating a self-aligned interconnect cap in accordance with one embodiment. Method 200 comprises depositing a conformal Cu seed layer 10 on insulator 05 (P210). Insulator 05 may be an oxide, such as SiO₂, a nitride, such as Si₃N₄ or, alternatively, the insulator 05 may be an interlayer dielectric which may have a low dielectric constant (low-k ILD). Other suitable insulators may also be used. In some embodiments, insulator 05 may have a plurality of vias, wells or trenches. Forming the Cu seed layer 10, in certain embodiments, may comprise depositing Cu on the inner walls and bottom of the vias, wells and/or trenches, as well as the top surface of the insulator 05 to provide seeding for further growth of Cu. As indicated earlier, Cu is disclosed as an exemplary metal, and other suitable metals may be used in other embodiments.

As shown in FIG. 2, a Cu-dopant alloy 30 may be deposited over the conformal Cu seed layer 10 by any of various deposition techniques (P220), such as plasma vapor deposition (PVD). The Cu-dopant alloy 30 may comprise, for example, one or more of Mn, Mg, B, Sn, Ti or Al. Other alloys found to be satisfactory for the method may also be chosen depending on implementation. Method 200 may further comprise deposition of Cu 20 over the layer of Cu-dopant alloy 30 previously deposited over the Cu seed layer 10 (P230). Cu 20 may be deposited such that Cu 20 substantially fills the vias, wells, and/or trenches to the extent of producing an over-burden of Cu. Depositing Cu 20, or other suitable metals, may comprise one or more processes such as electroless plating, chemical vapor deposition, atomic layer deposition, sputtering, or a metal immobilization process to activate a surface for electrochemical deposition. A chemical-mechanical planarization (CMP) may be performed to remove overburdens containing Cu to expose insulator 05 and the Cu deposited in the vias, wells, and/or trenches (P240).

In one embodiment, the planarized substrate may be treated to a diffusion annealing, whereby the dopant migrates by diffusion to accumulate at the top surface of the Cu. The dopant may then form an oxide or nitride cap 50 when treated with the appropriate gas composition. The layer so formed may have the property of a barrier to diffusion or electromigration of contaminant atoms, thereby maintaining the conductive properties of the Cu. The annealing may take place separately or simultaneously in the presence of an oxygen or nitrogen bearing vapor to promote formation of a self-aligned barrier cap of oxide or nitride of the dopant over the Cu. Concurrently, the annealing process causes diffusion of the dopant to migrate to the interface originally formed by the Cu seed layer 10 with the insulator 05 at the walls and bottom of the via, holes and/or trenches to form barrier 40. As described in process 100, the diffused dopant forms a dopant oxide or nitride layer (depending on the composition of insulator 05), providing an electromigration barrier.

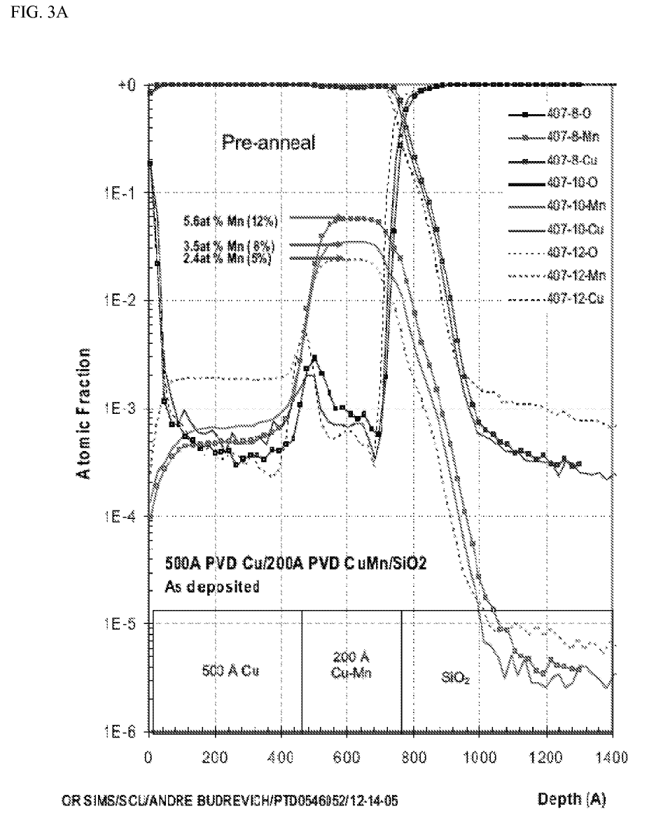

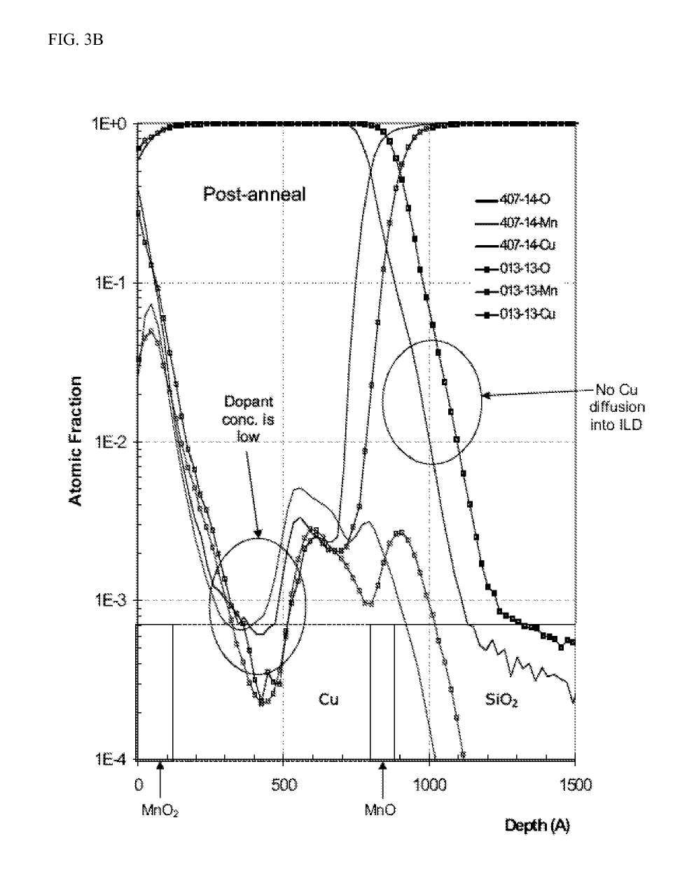

FIG. 3A provides secondary ion mass spectroscopy (SIMS) data for CuMn+Cu directly on an insulator surface showing pre-anneal distribution of Cu and Mn dopant alloy. Mn is shown as an example of a metal dopant's ability to migrate under annealing conditions. FIG. 3B provides secondary ion mass spectroscopy (SIMS) data for CuMn+Cu directly on an ILD surface showing post-anneal distribution of Cu and Mn dopant alloy. As shown, no diffusion of Cu is present to a significant distance into the ILD oxide SiO₂, as the Cu concentration decreases by about three orders of magnitude within about 500 Å of the original Cu—Mn boundary with SiO₂.

The various embodiments described above have been presented by way of example and not by way of limitation. Thus, for example, while embodiments disclosed herein teach the formation of protective nitride cap by plasma deposition, other methods of providing the nitride protective cap are also within the scope of embodiments. Cu deposition may be accomplished by a variety of vacuum or plasma methods, or may additionally employ electroless plating techniques.

It should be understood that the processes, methods, and the order in which the respective elements of each method are performed are purely exemplary. Depending on the implementation, they may be performed in a different order or in parallel, unless indicated otherwise in the present disclosure.

The method as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multi-chip package (such as a ceramic carrier that has either or both surface interconnections of buried interconnections).

In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method of forming a semiconductor device comprising:
depositing a first metal layer over an insulator formed over a substrate, wherein the insulator includes at least one via;
depositing a second metal layer over the first metal layer, such that the via is substantially filled with the second metal layer;
depositing a metal-dopant alloy over the second metal layer;
annealing the substrate to diffuse the dopant through the second metal layer and the first metal layer toward an interface between the first metal layer and the insulator to form a barrier layer between the first metal layer and the insulator;
planarizing the substrate to expose the insulator; and
depositing an etch-stop layer over the insulator and the via.

2. The method of claim 1, wherein the barrier layer comprises at least one of a metal oxide and metal nitride.

3. The method of claim 1, wherein the dopant comprises at least one of Mn, Sn, Mg, B, Ti, Al or a combination thereof.

4. The method of claim 1, wherein the insulator comprises at least one of an oxide, nitride, a low dielectric constant insulator or a combination thereof.

5. The method of claim 1, wherein the etch-stop layer comprises at least one of SiC, SiN, SiCN, or a combination thereof.

6. The method of claim 1, wherein the first metal layer is deposited over the insulator by way of at least one of plasma vapor deposition, chemical vapor deposition, atomic layer deposition, sputtering, and a metal immobilization process.

7. The method of claim 1, wherein at least one of the first metal layer, the second metal layer, and the metal-dopant alloy comprise Cu.

8. The method of claim 1 wherein the second metal layer is deposited by electroless plating.

9. The method of claim 1 wherein the metal-dopant alloy is deposited by plasma vapor deposition.

10. A semiconductor device comprising:
an insulator layer formed on a substrate;
a via formed by etching into the insulator layer to a first depth;
a first metal layer formed over the insulator layer;
a second metal layer deposited on the first metal layer to substantially fill the via;
a metal-dopant alloy layer deposited over the second metal, wherein the dopant is diffused by annealing through the second metal layer and the first metal layer deposited in the via, such that the dopant migrates to a boundary between the first metal layer and the insulator to form a barrier; and
an etch stop layer deposited over the via after planarization of the via and the insulator layer to form a barrier cap.

11. The semiconductor device of claim 10, wherein the insulator layer comprises at least one of SiO₂ and a low-dielectric constant interlayer insulator (low-k ILD).

12. The semiconductor device of claim 10, wherein the first metal layer is formed by way of at least one of plasma vapor deposition, chemical vapor deposition, atomic layer deposition, sputtering or metal immobilization process.

13. The semiconductor device of claim 10, wherein the dopant comprises one or more of Mn, Sn, Mg, B, Ti and Al or a combination thereof.

14. The semiconductor device of claim 10, wherein the etch-stop layer comprises one or more of SiC, SiN and SiCN.

15. The semiconductor device of claim 16, wherein at least one of the first metal layer, the second metal layer and the metal-dopant alloy comprise Cu.
